(19) United States
(12) Patent Application Publication
(10) Pub. No.: US 2019/0288183 A1
(43) Pub. Date: Sep. 19, 2019

(54) MAGNETIC DEVICE

(71) Applicant: TOSHIBA MEMORY CORPORATION, Tokyo (JP)

(72) Inventor: Hiroyuki KANAYA, Seoul (KR)

(73) Assignee: TOSHIBA MEMORY CORPORATION, Tokyo (JP)

(21) Appl. No.: 16/123,945

(22) Filed: Sep. 6, 2018

(30) Foreign Application Priority Data
Mar. 16, 2018 (JP) 2018-049302

(51) Int. Cl. H01L 43/02; G11C 11/16; H01F 10/32

(52) U.S. Cl. CPC H01L 43/02; H01L 43/12; H01F 10/3286; G11C 11/161

(57) ABSTRACT

According to one embodiment, a magnetic device includes: a first electrode above a substrate, the first electrode including a first portion and a second portion adjacent to the first portion in a direction parallel to a surface of the substrate; a second electrode above the first electrode; a first magnetic layer between the first electrode and the second electrode; a second magnetic layer between the first magnetic layer and the second electrode; and a non-magnetic layer between the first magnetic layer and the second magnetic layer, wherein an upper face of the first portion is located closer to the substrate than an upper face of the second portion.

### CROSS-REFERENCE TO RELATED APPLICATIONS

This application is based upon and claims the benefit of priority from Japanese Patent Application No. 2018-049302, filed Mar. 16, 2018, the entire contents of which are incorporated herein by reference.

### FIELD

Embodiments described herein relate generally to a magnetic device.

### BACKGROUND

Research and development on the structure and constituents of a magnetoresistive effect element have been promoted for improving the properties of the magnetoresistive effect element.

### BRIEF DESCRIPTION OF THE DRAWINGS

FIG. 1 is a diagram showing a configuration example of a memory device that includes a magnetic device of a first embodiment.

FIG. 2 is a diagram showing a configuration example of a memory cell array of the memory device.

FIG. 3 is a schematic cross-sectional diagram showing a structure example of the magnetic device of the first embodiment.

FIG. 4 is a top view schematically showing a structure example of the magnetic device of the first embodiment.

FIG. 5 is a cross-sectional diagram schematically showing a structure example of the magnetic device of the first embodiment.

FIGS. 6 to 13 are cross-sectional step diagrams respectively showing a step of a method of manufacturing the magnetic device of the first embodiment.

FIG. 14 is a diagram illustrating properties of the magnetic device of the first embodiment.

FIG. 15 is a cross-sectional diagram schematically showing a structure example of a magnetic device of a second embodiment.

FIG. 16 is a cross-sectional diagram schematically showing a structure example of a magnetic device of a third embodiment.

### DETAILED DESCRIPTION

In general, according to one embodiment, a magnetic device includes: a first electrode above a substrate, the first electrode including a first portion and a second portion adjacent to the first portion in a direction parallel to a surface of the substrate; a second electrode above the first electrode; a first magnetic layer between the first electrode and the second electrode; a second magnetic layer between the first magnetic layer and the second electrode; and a non-magnetic layer between the first magnetic layer and the second magnetic layer, wherein an upper face of the first portion is located closer to the substrate than an upper face of the second portion.

### Embodiments

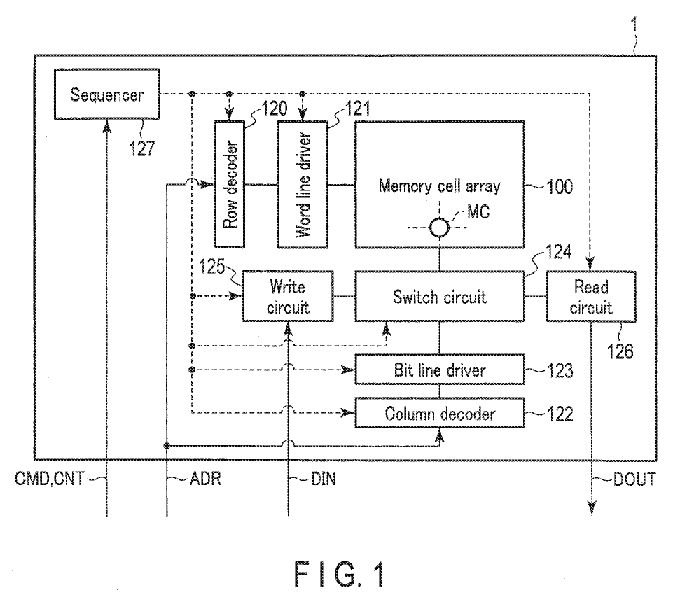

Hereinafter, the present embodiments will be described in detail with reference to the accompanying drawings (FIGS. 1 to 16). In the description below, elements having the same functions and configurations will be denoted by the same reference symbols.

Also, in the embodiments described below, when elements are denoted by reference symbols (e.g., a word line WL, a bit line BL, various voltages and signals, and the like) with numbers or alphabetical characters for distinction but are not necessarily distinguished from each other, such numbers or alphabetical characters may be omitted in the description.

### (1) First Embodiment

A magnetic device of a first embodiment and a method of manufacturing the same will be described with reference to FIGS. 1 to 14.

### (a) Configuration Example

A configuration example of the magnetic device of the first embodiment will be described with reference to FIGS. 1 to 5.

FIG. 1 is a block diagram illustrating a configuration example of a memory device that includes the magnetic device of the present embodiment.

In FIG. 1, a memory device 1 that includes the magnetic device of the present embodiment is electrically coupled to an external device such as a controller, processor, or host device.

The memory device 1 receives a command CMD, an address ADR, input data DIN, and various control signals CNT from the external device. The memory device 1 transmits output data DOUT to the external device.

As shown in FIG. 1, the memory device 1 includes at least a memory cell array 100, a row decoder 120, a word line driver (row line control circuit) 121, a column decoder 122, a bit line driver (column line control circuit) 123, a switch circuit 124, a write circuit (write control circuit) 125, a read circuit (read control circuit) 126, and a sequencer 127.

The memory cell array 100 includes a plurality of memory cells MC.

The row decoder 120 decodes a row address included in the address ADR.

The word line driver 121 selects a row (e.g., word line) of the memory cell array 100 based on a result of decoding the row address. The word line driver 121 can supply a predetermined voltage to the word line.

The column decoder 122 decodes a column address included in the address ADR.

The bit line driver 123 selects a column (e.g., bit line) of the memory cell array 100 based on a result of decoding the column address. The bit line driver 123 is coupled to the memory cell array 100 via the switch circuit 124. The bit line driver 123 can supply a predetermined voltage to the bit line.

The switch circuit 124 couples one of the write circuit 125 or the read circuit 126 to the memory cell array 100 and the bit line driver 123. Thereby, the memory device 1 executes an operation corresponding to a command.

In a write operation, the write circuit 125 supplies a selected cell based on the address ADR with various voltages and/or currents for writing data. For example, the data DIN is supplied to the write circuit 125 as data to be written to the memory cell array 100. Thereby, the write circuit 125 writes the data DIN in the memory cell MC. The write circuit 125 includes, for example, a write driver/sinker.

In a read operation, the read circuit 126 supplies a memory cell selected based on the address ADR (selected cell) with various voltages and/or currents for reading data. Thereby, the data stored in the memory cell MC is read.

The read circuit 126 outputs, to the outside of the memory device 1, data read from the memory cell array 100 as the output data DOUT.

The read circuit 126 includes, for example, a read driver and a sense amplifier circuit.

The sequencer 127 receives a command CMD and various control signals CNT. The sequencer 127 controls an operation of each of the circuits 120 to 126 in the memory device 1 based on the command CMD and the control signals CNT. The sequencer 127 can transmit the control signals CNT to the external device according to an operation state in the memory device 1.

For example, the sequencer 127 holds various information related to the write operation and the read operation as setting information.

The various signals CMD, CNT, ADR, DIN, and DOUT may be supplied to a predetermined circuit in the memory device 1 via an interface circuit provided separately from a chip (package) of the memory device 1, or may be supplied to the respective circuits 120 to 127 from an input-output circuit (not illustrated in the drawings) in the memory device 1.

In the present embodiment, the memory device 1 is, for example, a magnetic memory. In the magnetic memory (e.g., MRAM), the magnetic device of the present embodiment is a magnetoresistive effect element. The magnetoresistive effect element of the present embodiment is used for a memory element in the memory cell MC.

<Internal Configuration of Memory Cell Array>

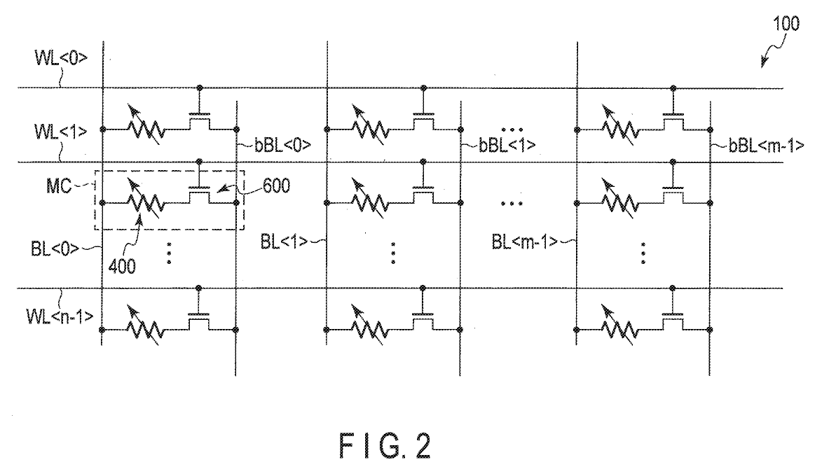

FIG. 2 is an equivalent circuit diagram showing an example of an internal configuration of the memory cell array of the MRAM according to the present embodiment.

As illustrated in FIG. 2, multiple (n) word lines WL (WL<0>, WL<1>, . . . WL<n−1>) are provided in the memory cell array 100. Multiple (m) bit lines BL (BL<0>, BL<1>, . . . , BL<m−1>) and multiple (m) bit lines bBL (bBL<0>, bBL<1>, . . . , bBL<m−1>) are provided in the memory cell array 100. One bit line BL and one bit line bBL form a pair of bit lines. In the description below, the bit line bBL may be referred to as a source line for the sake of clarity of the description.

The memory cells MC are arranged in a matrix in the memory cell array 100.

The memory cells MC aligned in an x-direction (row direction) are coupled to a common word line WL. The word lines WL are coupled to the word line driver 121. The word line driver 121 controls the potential of the word lines WL based on the row address. Thereby, a word line WL (row) indicated by the row address is selected and activated.

The memory cells MC aligned in a y-direction (column direction) are coupled in common to two bit lines BL and bBL that belong to a pair of bit lines. The bit lines BL and bBL are coupled to the bit line driver 123 via the switch circuit 124.

The switch circuit 124 couples the bit lines BL and bBL corresponding to the column address to the bit line driver 123. The bit line driver 123 controls the potential of the bit lines BL and bBL. Thereby, bit lines BL and bBL (column) indicated by the column address are selected and activated.

Also, the switch circuit 124 couples the selected bit lines BL and bBL to the write circuit 125 or the read circuit 126 according to an operation required of the memory cell MC.

For example, the memory cell MC includes one magnetoresistive effect element 400 and one cell transistor 600.

One end of the magnetoresistive effect element 400 is coupled to the bit line BL. The other end of the magnetoresistive effect element 400 is coupled to one end (one of a source or drain) of the cell transistor 600. The other end (the other of the source or drain) of the cell transistor 600 is coupled to the bit line bBL. The word line WL is coupled to a gate of the cell transistor 600.

The memory cell MC may include two or more magnetoresistive effect elements 400 and may include two or more cell transistors 600.

The memory cell array 100 may have a structure of a hierarchical bit line form. In this case, a plurality of global bit lines are provided in the memory cell array 100. Each bit line BL is coupled to one global bit line via a corresponding switch element. Each source line bBL is coupled to another global bit line via a corresponding switch element. The global bit lines are coupled to the write circuit 125 and the read circuit 126 via the switch circuit 124.

The magnetoresistive effect element 400 functions as a memory element. The cell transistor 600 functions as a selected element of the memory cell MC.

A resistance state (magnetization alignment) of the magnetoresistive effect element 400 changes when a voltage or current having a certain magnitude is supplied to the magnetoresistive effect element 400. Thereby, the magnetoresistive effect element 400 may take multiple resistance states (resistance values). Data of 1 or larger bits is associated with the multiple resistance states that the magnetoresistive effect element 400 may take. In this manner, the magnetoresistive effect element 400 is used as a memory element.

<Structure Example of Memory Cell>

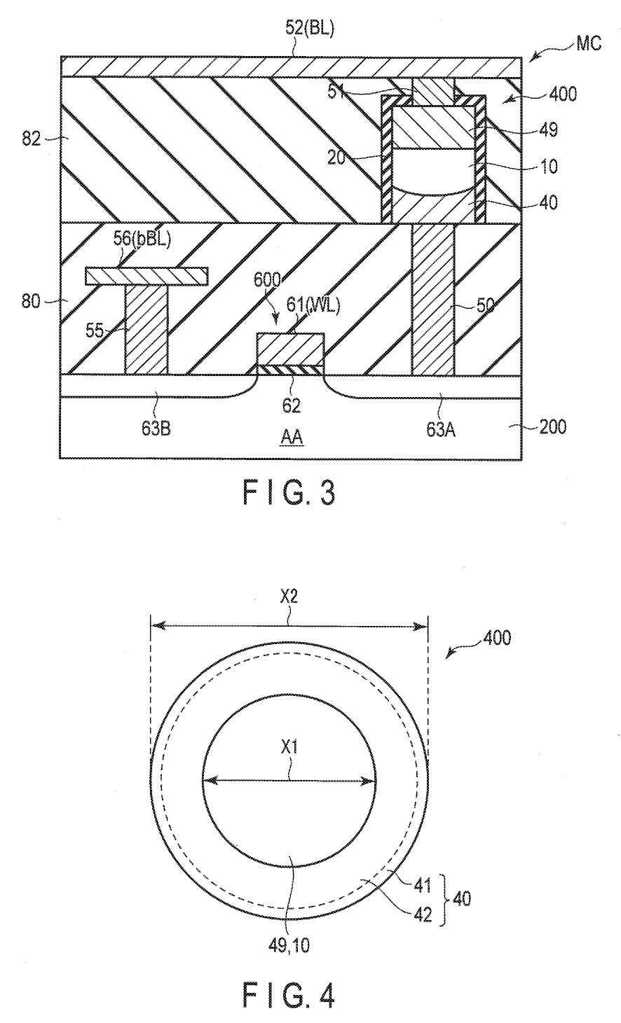

FIG. 3 is a cross-sectional diagram showing a structure example of the memory cell of the MRAM according to the present embodiment.

As illustrated in FIG. 3, the memory cell MC is provided on a semiconductor substrate 200.

The cell transistor 600 is a transistor of any type. For example, the cell transistor 600 is a field-effect transistor having a planar structure, a field-effect transistor having a three-dimensional structure, such as FinFET, or a field-effect transistor having a buried gate structure. In the description below, a cell transistor having a planar structure will be illustrated as an example.

The cell transistor 600 is provided in an active area (semiconductor area) AA of the semiconductor substrate 200.

In the cell transistor 600, a gate electrode 61 is provided above the active area AA via a gate insulator film 62. The gate electrode 61 extends in a depth direction (or toward the front) in FIG. 3. The gate electrode 61 functions as the word line WL.

Source/drain regions 63A and 63B of the cell transistor 600 are provided in the active area AA.

A contact plug 55 is provided on the source/drain region 63B. An interconnect (metal film) 56 as the bit line bBL is provided on the contact plug 55.

A contact plug 50 is provided on the source/drain region 63A.

The magnetoresistive effect element 400 is provided on the contact plug 50 and an interlayer insulator film 80. The magnetoresistive effect element 400 is provided in an interlayer insulator film 82.

The magnetoresistive effect element 400 includes two electrodes 40 and 49, and a stack 10 between the two electrodes 40 and 49. The stack 10 is a multi-layer film having a magnetic tunnel junction.

In the present embodiment, the magnetoresistive effect element 400 having a magnetic tunnel junction is referred to as an MTJ element.

The electrode 40 is provided on the contact plug 50. The electrode 49 is provided above the electrode 40 via the stack 10. A via plug 51 is provided on the electrode 49. An interconnect (metal film) 52 as the bit line BL is provided on the via plug 51 and the interlayer insulator film 82. A conductive layer (e.g., metal film) may be provided between the electrode 40 and the contact plug 50.

In the magnetoresistive effect element 400 of the present embodiment, the electrode 40 on the semiconductor substrate 200 side is referred to as a lower electrode 40, and the electrode 49 opposite to the semiconductor substrate 200 side is referred to as an upper electrode 49.

For example, an insulator film (hereinafter also referred to as a protective film or a sidewall insulator film) 20 covers a lateral face of the MTJ element 400. The protective film 20 is provided between the interlayer insulator film 82 and the tunnel junction 10. The protective film 20 may be provided between the interlayer insulator film 82 and the electrodes 40 and 49.

A material of the protective film 20 is selected from, for example, silicon nitride, aluminum nitride, and aluminum oxide. The protective film 20 may be a single-layer film or a multi-layer film.

The protective film 20 need not be provided. Also, the shape of the protective film 20 shown in FIG. 3 can be adjusted as appropriate.

FIG. 3 is a simplified view of the structure of the magnetoresistive effect element. In FIG. 3, the stack (magnetic tunnel junction) 10 and the electrodes 40 and 49 are also shown in a simplified manner. Namely, in the present embodiment, the configurations of the memory cell array and the memory cell are not limited to the examples shown in FIGS. 2 and 3.

The stack 10 and the electrodes 40 and 49 of the magnetoresistive effect element of the present embodiment will be described in more detail below.

<Structure Example of Magnetoresistive Effect Element>

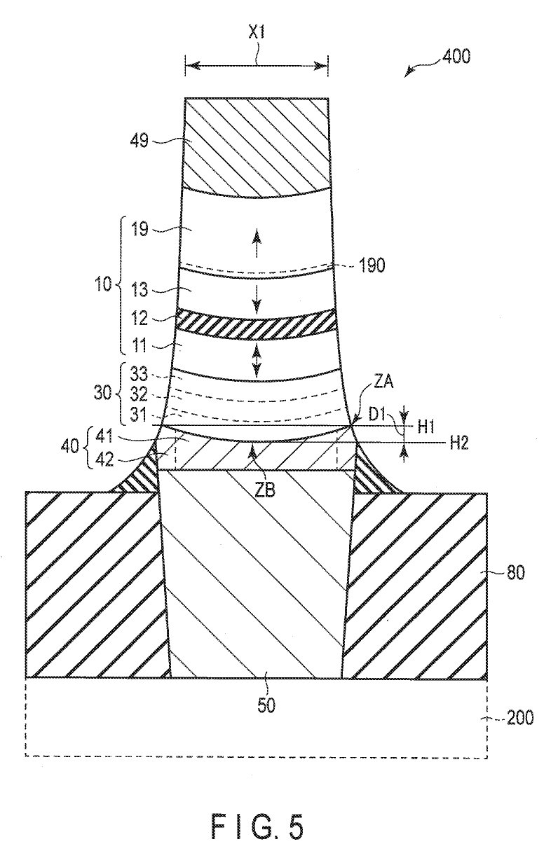

A structure of the magnetoresistive effect element (MTJ element) of the present embodiment will be described with reference to FIGS. 4 and 5.

FIG. 4 is a schematic plan view showing a structure example of the MTJ element of the present embodiment. FIG. 5 is a schematic cross-sectional diagram showing a structure example of the MTJ element of the present embodiment. In FIGS. 4 and 5, the protective film 20 and the interlayer insulator film are not shown for the sake of clarity of the figures.

The MTJ element 400 of the embodiment illustrated in FIGS. 4 and 5 has a truncated cone shape.

As shown in FIG. 4, the MTJ element 400 of the present embodiment has a circular (or oval) planar shape. As shown in FIG. 5, the magnetoresistive effect element 400 of the present embodiment has a trapezoidal cross-section shape.

The structure of the MTJ element 400 is not limited to a truncated cone shape. For example, the planar shape of the MTJ element 400 may be quadrilateral (e.g., square or rectangular). Also, in an MTJ element having a quadrilateral planar shape, the corners of the quadrilateral may be rounded off.

For example, a dimension X2 of a lower portion of the MTJ element 400 (on the substrate 200 side and the electrode 40 side), in a direction parallel to a surface of the substrate 200, is larger than a dimension X1 of an upper portion of the MTJ element 400 (opposite to the substrate 200 and on the electrode 49 side), in the direction parallel to the surface of the substrate 200.

In the MTJ element 400, the stack (magnetic tunnel junction) 10 includes at least two magnetic layers 11 and 13 and a non-magnetic layer 12.

The non-magnetic layer 12 is provided between the two magnetic layers 11 and 13.

The magnetic layer 11, which is one of the two magnetic layers, is provided between the upper electrode 49 and the non-magnetic layer 12. The other magnetic layer 13 is provided between the non-magnetic layer 12 and the lower electrode 40.

The magnetic tunnel junction is formed between the non-magnetic layer 12 and the magnetic layers 11 and 13.

In the MTJ element 400, the non-magnetic layer 12 is referred to as a tunnel barrier layer 12. The tunnel barrier layer 12 is, for example, an insulator film including magnesium oxide (MgO).

The two magnetic layers 11 and 13 have magnetization. The magnetic layer 11, which is one of the two magnetic layers, is a magnetic layer having a variable direction of magnetization. The other magnetic layer 13 is a magnetic layer having an invariable direction of magnetization. In the description below, the magnetic layer 11 having a variable direction of magnetization is referred to as a storage layer 11, and the magnetic layer 13 having an invariable direction of magnetization is referred to as a reference layer 13. The storage layer 11 may also be referred to as a free layer or a free magnetization layer. The reference layer 13 may also be referred to as a pin layer, a pinned layer, a fixed magnetization layer, or an invariable magnetization layer.

A direction of magnetization of the reference layer 13 “being invariable” or “being fixed” means that a direction of magnetization of the reference layer 13 does not vary between before and after a current or voltage for switching a direction of magnetization of the storage layer 11 is supplied to the MTJ element 400. A magnetization switching threshold value of the storage layer 11 and a magnetization switching threshold value of the reference layer 13 are controlled so that the direction of magnetization of the reference layer 13 is invariable. For example, in order to control the magnetization switching threshold values, a film thickness of the reference layer 13 is set to be larger than a film thickness of the storage layer 11 if the storage layer and the reference layer are the same material system.

The storage layer 11 and the reference layer 13 are, for example, magnetic layers having perpendicular magnetic anisotropy. The magnetization of the storage layer 11 and the magnetization of the reference layer 13 are approximately perpendicular to a layer face of the magnetic layers 11 and 13. A magnetization direction (magnetization easy axis direction) of the magnetic layers 11 and 13 is approximately parallel to the stacking direction of the two magnetic layers 11 and 13. The magnetization of the storage layer 11 is oriented toward the upper electrode side or the lower electrode side depending on the data to be stored. The fixed magnetization of the reference layer 13 is set (fixed) to be oriented toward either one of the upper electrode side or the lower electrode side.

The storage layer 11 includes cobalt iron boron (CoFeB) or iron boride (FeB).

The tunnel barrier layer 12 is, for example, magnesium oxide or an insulating compound including magnesium oxide.

The reference layer 13 includes, for example, cobalt iron boron (CoFeB) or iron boride (FeB). The reference layer 13 may also include cobalt platinum (CoPt), cobalt nickel (CoNi), or cobalt palladium (CoPd). The reference layer 13 is, for example, an alloy film or a multi-layer using these materials.

A shift canceling layer 19 is provided between the reference layer 13 and the upper electrode 49. The shift canceling layer 19 is a magnetic layer for reducing a stray magnetic field of the reference layer 13. A direction of magnetization of the shift canceling layer 19 is opposite to the direction of magnetization of the reference layer 13. Thereby, a negative influence (e.g., magnetic field shift) on the magnetization of the storage layer 11 due to a stray magnetic field of the reference layer 13 is inhibited. For example, a material of the shift canceling layer 19 is the same as the material of the reference layer 13.

For example, the direction of magnetization of the reference layer 13 and the direction of magnetization of the shift canceling layer 19 are set to be opposite to each other by a SAF (synthetic antiferromagnetic) structure.

In the SAF structure, an intermediate layer 190 is provided between the reference layer 13 and the shift canceling layer 19. The intermediate layer 190 couples the reference layer 13 and the shift canceling layer 19 in an antiferromagnetic manner. The intermediate layer 190 is a non-magnetic metal film of ruthenium (Ru) or the like. A stack (SAF structure) that includes the magnetic layers 11 and 19 and the intermediate layer 190 may be referred to as a reference layer.

The MTJ element 400 shown in FIG. 5 is, for example, an MTJ element having a bottom free structure.

In the MTJ element 400 of the present embodiment, the storage layer 11 is located closer to the substrate side than the reference layer 13. The storage layer 11 is provided between the reference layer 13 and the substrate. For example, a dimension of the storage layer 11 in the direction parallel to the surface of the substrate is larger than a dimension of the reference layer 13 in the direction parallel to the surface of the substrate.

A resistance state (resistance value) of the MTJ element 400 varies in accordance with a relative relationship (magnetization alignment) between the direction of magnetization of the storage layer 11 and the direction of magnetization of the reference layer 13.

When the direction of magnetization of the storage layer 11 is the same as the direction of magnetization of the reference layer 13 (when the magnetization alignment of the MTJ element 400 is in a parallel alignment state), the MTJ element 400 has a first resistance value R1. When the direction of magnetization of the storage layer 11 is different from the direction of magnetization of the reference layer 13 (when the magnetization alignment of the MTJ element 400 is in an anti-parallel alignment state), the MTJ element 400 has a second resistance value R2 that is higher than the first resistance value R1.

In the present embodiment, the parallel alignment state of the MTJ element 400 is also indicated as a P state, and the anti-parallel alignment state of the MTJ element 400 is also indicated as an AP state.

For example, when the memory cell MC stores 1-bit data (“0” data or “1” data), first data (e.g., “0” data) is associated with the MTJ element 400 in a state of having the first resistance value R1 (first resistance state). Second data (e.g., “1” data) is associated with the MTJ element 400 in a state of having the second resistance value R2 (second resistance state).

The MTJ element 400 may be an in-plane magnetization-type MTJ element. In the in-plane magnetization-type MTJ element, the magnetization of the storage layer 11 and the reference layer 13 is oriented toward a direction perpendicular to the stacking direction of the magnetic layers 11 and 13. In the in-plane magnetization-type MTJ element, the magnetization easy axis direction of the storage layer and the reference layer is parallel to the layer face of the magnetic layers 11 and 13.

For example, a layer (hereinafter referred to as an underlying layer) 30 is provided between the lower electrode 40 and the magnetic layer 13. The underlying layer 30 is a layer capable of improving the properties of the magnetic layer 13 (e.g., magnetic properties and/or crystallinity of the magnetic layer), and/or the properties of the magnetic tunnel junction.

For example, the underlying layer 30 includes multiple (e.g., three) layers 31, 32, and 33 made of different materials.

The underlying layer 30 includes at least one of metal, boride, oxide, nitride, or the like.

For example, a metal used in the underlying layer 30 is selected from aluminum (Al), beryllium (Be), magnesium (Mg), calcium (Ca), strontium (Sr), barium (Ba), scandium (Sc), yttrium (Y), lanthanum (La), silicon (Si), zirconium (Zr), hafnium (Hf), tungsten (W), chromium (Cr), molybdenum (Mo), niobium (Nb), titanium (Ti), tantalum (Ta), vanadium (V), or the like. A boride, oxide, and nitride of these metals, for example, are used in the underlying layer 30. Various compounds used in the underlying layer 30 may be binary compounds or ternary compounds.

A layer 31 of the underlying layer 30 is, for example, a boride layer. A layer 32 is, for example, a metal layer. A layer 33 is, for example, a nitride layer.

The underlying layer 30 may be a single-layer film made of one material, two-layer film made of two different materials, or a multi-layer film made of four or more different materials.

An insulating compound including a material of the underlying layer 30 may be used as a material of the protective film 20.

The upper electrode 49 is provided above the magnetic tunnel junction 10. The upper electrode 49 is provided on the shift canceling layer 19. A material of the upper electrode 49 includes, for example, at least one of tungsten (W), tantalum (Ta), tantalum nitride (TaN), titanium (Ti), titanium nitride (TiN), or the like.

The lower electrode 40 is provided below the magnetic tunnel junction 10. The lower electrode 40 is provided between the contact plug 50 and the underlying layer 30. A material of the lower electrode 40 includes, for example, at least one of tungsten, tantalum, tantalum nitride, titanium, titanium nitride, or the like.

Each of the electrodes 40 and 49 may be a single-layer structure or a multi-layer structure.

As illustrated in FIG. 5 (and FIG. 3), the lower electrode 40 between the stack (magnetic tunnel junction) 10 and the substrate 200 in the MTJ element 400 of the present embodiment has a concave cross-sectional shape.

The lower electrode 40 has a convex surface facing a downward direction (the substrate side). In the description below, a face of the lower electrode 40 on the magnetic tunnel junction 10 side (face having a convex shape facing a downward direction) is referred to as an upper face of the lower electrode 40. A face opposed to the upper face of the lower electrode 40 in a direction perpendicular to the surface of the substrate 200 is referred to as a lower face (or bottom face).

The upper face of the lower electrode 40 is bent. As a result, a depression is provided in an upper portion of the lower electrode 40. The magnetic layers 11 and 13 and the tunnel barrier layer 12 are formed above the upper face of the lower electrode 40 rounded by the bending.

The lower face of the lower electrode 40 is substantially parallel to the surface of the substrate 200 (the interlayer insulator film 80, or the contact plug 50).

In this manner, the upper face of the lower electrode 40 is a curved face, and the lower face of the lower electrode 40 is a plane.

The lower electrode 40 includes a portion 41 on a central side of the electrode 40 (hereinafter referred to as a central portion 41), and a portion 42 on an outer periphery side of the electrode 40 (hereinafter referred to as an outer portion 42). The central portion 41 is surrounded by the outer portion 42 in a direction parallel to the surface of the substrate. For example, the outer portion 42 is provided between the central portion 41 and the protective film 20 shown in FIG. 3.

An upper face of the central portion 41 is located closer to the substrate 200 side than an upper face of the outer portion 42.

The highest position (end portion) ZA in the upper face of the outer portion 42 in the direction perpendicular to the surface of the substrate 200 is at a height H1 with respect to the surface (upper face) of the contact plug 50 (substrate 200, or interlayer insulator film 80). The lowest position (end portion) ZB in the upper face of the central portion 41 in the direction perpendicular to the surface of the substrate 200 is at a height H2 with respect to the surface of the contact plug 50. For example, the position ZB is arranged on a central axis of the MTJ element 400.

A difference D1 between the height H1 at the outer portion 42 and the height H2 at the central portion 41 (a depth D1 of the depression of the upper face of the lower electrode 40) is within a range of 5 Å (0.5 nm) to 30 Å (3 nm), for example.

For example, a ratio between the dimension D1 and the dimension X1 (D1/X1) is preferably in a range of 0.01 to 0.10.

“H1” may be regarded as a film thickness from a bottom face of the outer portion 42 to the end portion ZA (the highest portion of the upper face of the lower electrode 40). “H2” may be regarded as a film thickness from a bottom face of the central portion 41 to the end portion ZB (the lowest portion of the upper face of the lower electrode 40).

The film thickness H1 from the lower face of the electrode 40 to the end portion ZA is larger than the film thickness H2 from the lower face of the electrode 40 to the end portion ZB. For example, the central portion 41 does not include a portion having a film thickness that is larger than the film thickness H1.

Each of the layers 11, 12, 13, 19, and 30 forming the magnetic tunnel junction 10 is formed on the bent upper face (curved face) of the lower electrode 40. For example, the upper face of the lower electrode 40 contacts the underlying layer 30.

Each of the layers 11, 12, 13, 19, and 30 above the lower electrode 40 is bent according to the lower electrode 40 having a concave cross-sectional shape.

For example, each of the layers 11, 12, 13, 19, and 30 has a cross-sectional shape (convex shape) with a convex part facing a downward direction. The central portion of each of the layers 11, 12, 13, 19, and 30 is located closer to the substrate side than the end portion of each of the layers 11, 12, 13, 19, and 30.

An upper part of the end portion (edge) of each of the layers 11, 12, 13, 19, and 30 in the direction parallel to the surface of the substrate 200 is located in a higher position (opposite to the substrate 200 side) than an upper part of the central portion of each of the layers 11, 12, 13, 19, and 30. A bottom part (lower part) of the end portion (edge) of each of the layers 11, 12, 13, 19, and 30 in the direction parallel to the surface of the substrate 200 is located in a higher position (opposite to the substrate 200 side) than a bottom part of the central portion of each of the layers 11, 12, 13, 19, and 30.

For example, if a difference in height (difference in level) between the portion ZA and the portion ZB of the upper face of the lower electrode 40 is in a range of 5 Å to 30 Λ, a difference in level between the end portion (corresponding to “ZA”) and the central portion (corresponding to “ZB”) of the magnetic layers 11 and 13 bent to have a convex part (a convex shape) on the substrate 200 side, and a difference in level between the end portion and the central portion of the tunnel barrier layer 12 bent to have a convex part on the substrate 200 side have a value within a range of about 5 Å to 30 Å.

In the present embodiment, the properties of the MTJ element 400 are improved by the above-described structure of the lower electrode 40.

The operation of the MRAM that includes the MTJ element 400 of the present embodiment can suitably adopt well-known data write operations and well-known data read operations. Therefore, in the present embodiment, description of the operation of the MRAM that includes the MTJ element 400 of the present embodiment is omitted.

### (b) Manufacturing Method

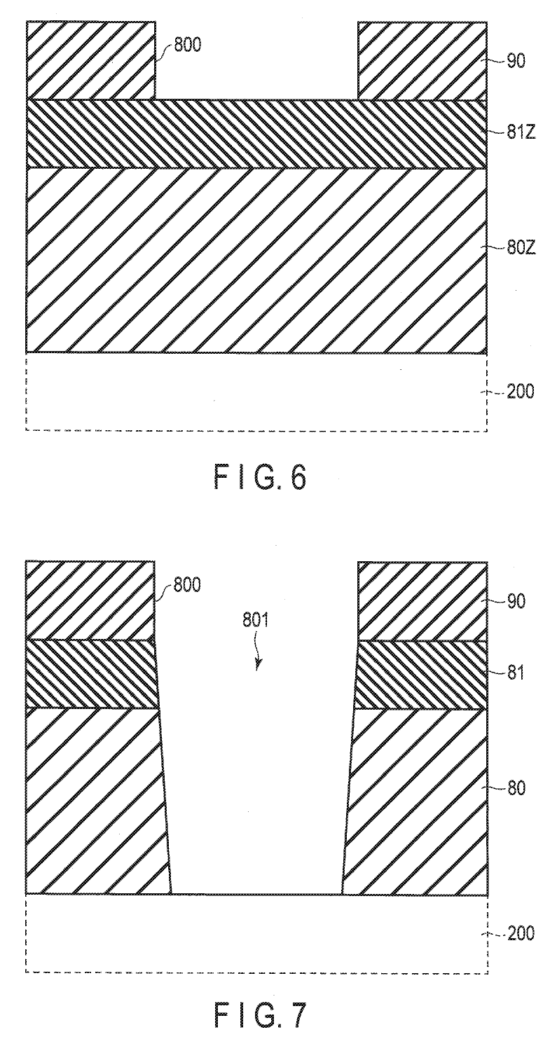

A method of manufacturing the magnetic device according to the present embodiment will be described with reference to FIGS. 6 to 13. In the description below, FIGS. 3 to 5 will also be referred to as necessary.

FIGS. 6 to 13 are process cross-sectional diagrams illustrating each step of the method of manufacturing the magnetoresistive effect element (MTJ element) according to the present embodiment.

As illustrated in FIG. 6, after an element (e.g., cell transistor shown in FIG. 3) is formed on the substrate 200, an insulator layer (interlayer insulator film) 80Z is formed on the substrate 200 by a film formation technique such as CVD (chemical vapor deposition). The insulator layer 80Z is, for example, a silicon oxide (SiO₂) layer.

An insulator layer (interlayer insulator film) 81Z is formed on the insulator layer 80Z by, for example, the CVD method. The insulator layer 81Z is, for example, a silicon nitride (SiN) layer.

A mask layer (e.g., resist mask) 90 having a predetermined pattern 800 is formed on the insulator layer 81Z. The pattern 800 of the mask layer 90 is formed by the well-known lithography technique and etching technique. For example, the mask layer 90 has an opening pattern 800 having a circular planar shape. The opening pattern 800 is formed in a region where a contact plug is formed.

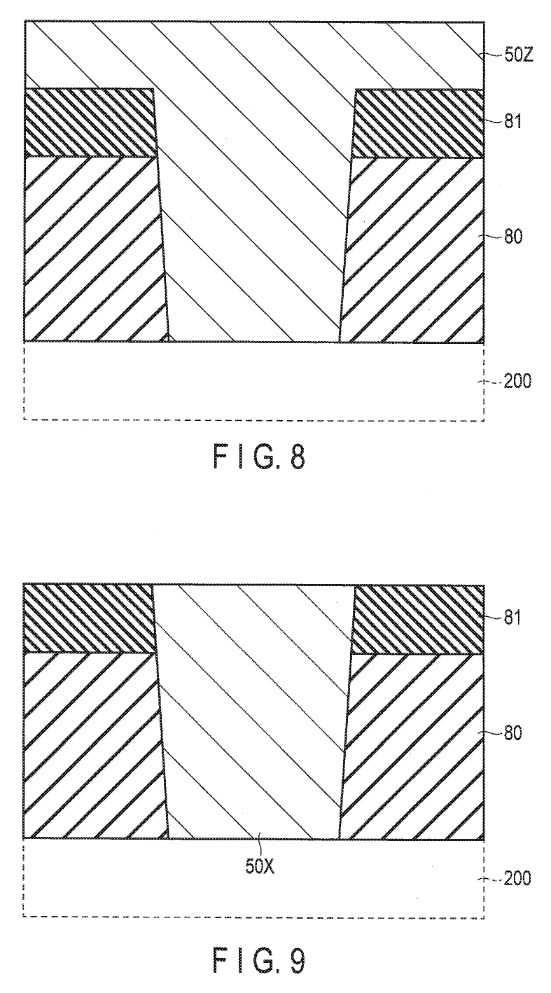

As illustrated in FIG. 7, an etching is performed based on a pattern of the mask layer 90.

Thereby, a contact hole 801 is formed in the insulator layer 80 and the insulator layer 81.

As illustrated in FIG. 8, after the mask layer is removed, a conductor 50Z is formed on the interlayer insulator film 80 and the insulator layer 81 so as to fill the contact hole. The conductor 50Z is, for example, titanium nitride (TiN) or tungsten (W).

An upper face of the insulator layer 81 is used as a stopper to perform planarization processing such as the CMP (chemical mechanical polishing) method on the conductor. In this step, the upper face of the insulator layer 81 may be slightly scraped according to the conditions of the CMP.

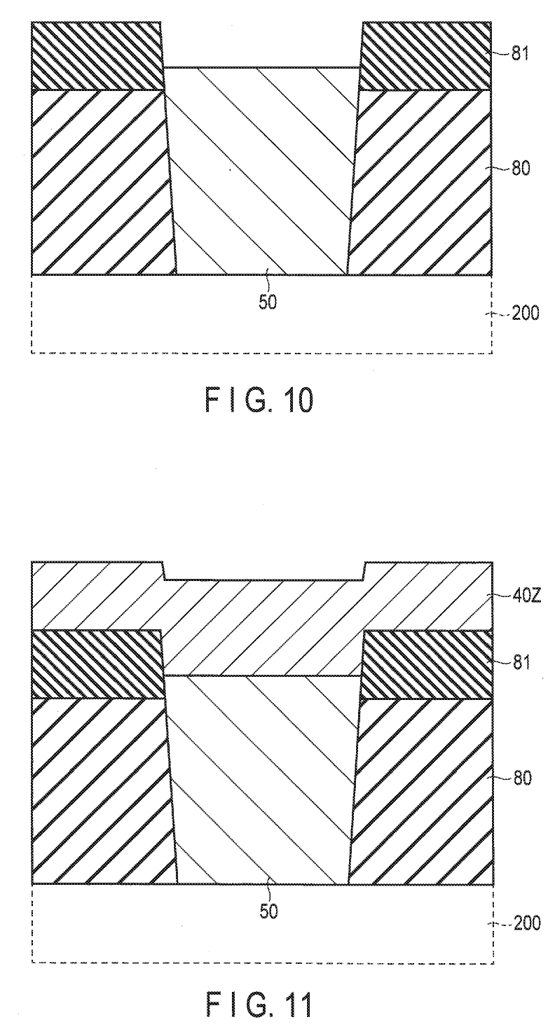

Thereby, a position of an upper portion of a conductor 50X is aligned with a position of an upper portion of the insulator layer 81, as shown in FIG. 9.

As illustrated in FIG. 10, recess formation processing (etch-back processing) is performed on the conductor. An upper face of the conductor 50 is selectively etched. Thereby, a position of the upper face of the conductor 50 recedes further toward the insulator layer 80 side (substrate side) than a position of the upper face of the insulator layer 81.

As a result, the contact plug 50 is formed in the insulator layer 80.

As illustrated in FIG. 11, a conductive layer 40Z is formed on the contact plug 50 and the insulator layer 81. For example, an upper face of the conductive layer 40Z is depressed according to a difference in level between the upper face of the contact plug 50 and the upper face of the insulator layer 81. Thereby, a part of the upper face of the conductive layer 40Z that is above the contact plug 50 is positioned closer to the substrate 200 side than a part of the upper face of the conductive layer 40Z that is above the insulator layer 80.

A material of the conductive layer 40Z is, for example, one or more selected from tungsten, tantalum, tantalum nitride, titanium, and titanium nitride.

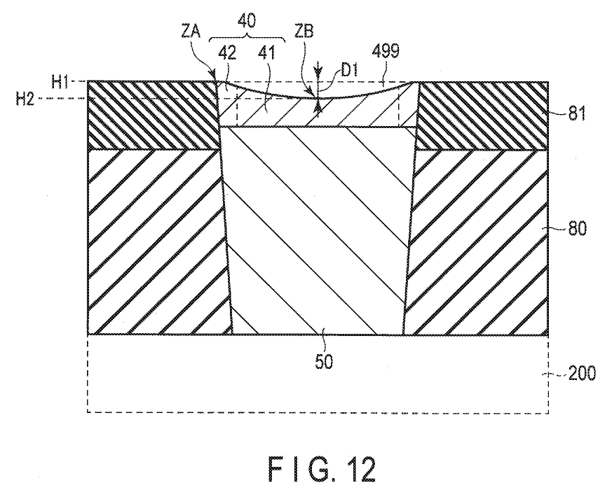

As illustrated in FIG. 12, the upper face of the insulator layer 81 is used as a stopper to perform the CMP processing on the conductive layer 40.

In the present embodiment, the conditions of the CMP processing performed on the conductive layer 40 are set so that a dishing having a predetermined size (depth) D1 is created in an upper face of the conductive layer 40.

The upper face of the conductive layer 40Z recedes toward the substrate 200 side, as compared to the upper face of the insulator layer 81.

As a result, a depression 499 is formed in the upper face of the conductive layer 40. The creation of the dishing results in a bending of the upper face of the conductive layer 40Z above the contact plug 50.

A depth D1 of the depression 499 (difference between the height H1 of the end portion ZA of the outer portion 42 and the height H2 of the end portion ZB of the central portion 41) has a value within a range of 5 Å to 30 Å, for example.

In this manner, the lower electrode 40 having a concave shape is formed. The lower electrode 40 has a curve on its upper face.

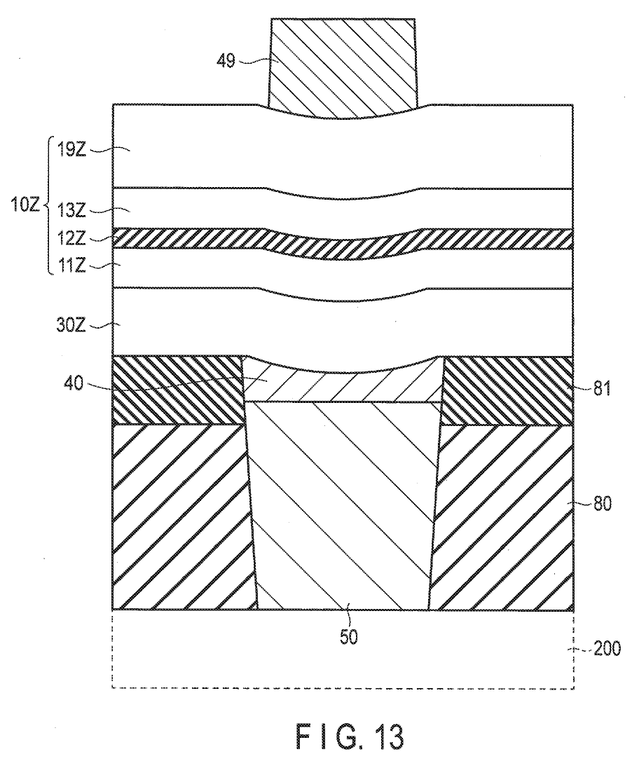

As illustrated in FIG. 13, an underlying layer 30Z is formed on the upper face of the lower electrode 40 having a concave shape by, for example, the sputtering method.

A stack 10Z is formed on the underlying layer 30 by, for example, the sputtering method.

The stack 10Z includes, for example, a magnetic layer 11Z, a non-magnetic layer 12Z, a magnetic layer 13Z, and a magnetic layer 19Z. The magnetic layer 11Z is formed on the underlying layer 30Z. The non-magnetic layer 12Z is formed on the magnetic layer 11Z. The magnetic layer 13Z is formed on the non-magnetic layer 12Z. The magnetic layer 19Z is formed on the magnetic layer 13Z.

Above the contact plug 50, each of the layers 11Z, 12Z, 13Z, 19Z, and 30Z is bent according to the shape of the upper face of the lower electrode 40 (depression of the upper face of the lower electrode 40). For example, a portion, above the contact plug 50, of each of the layers 11Z, 12Z, 13Z, 19Z, and 30Z has a convex cross-sectional shape facing a downward direction.

The hard mask 49 is formed on the magnetic layer 19Z in a position above the contact plug 50. The hard mask 49 has a predetermined pattern made by the lithography technique and the etching technique. The hard mask 49 is patterned based on a shape of an MTJ element to be formed. A material of the hard mask 49 is, for example, one or more selected from tungsten, tantalum, tantalum nitride, titanium, and titanium nitride.

The hard mask 49 is used as a mask to perform etching on the stack 10Z and the underlying layer 30Z.

For example, the stack 10Z and the underlying layer 30Z are processed into a shape corresponding to the hard mask 49 by ion beam etching. An ion beam is, for example, radiated to the stack 10Z at an inclined angle with respect to the surface of the substrate.

Thereby, the MTJ element 400 of the present embodiment is formed, as shown in FIGS. 4 and 5.

A type of etching performed on the stack 10Z and the underlying layer 30Z is not limited to ion beam etching.

For example, the insulator film (protective film) 20 is formed on the lateral face of the MTJ element 400, as illustrated in FIG. 3. At least one of an oxidation treatment or a nitriding treatment may be performed before formation of the insulator film 20, in order to isolate a substance attached to the lateral face of the MTJ element 400. The insulator film 20 may be formed by isolating a substance attached to the lateral face of the MTJ element 400.

An insulator layer 82 is formed on the insulator layer 80 and the MTJ element 400 so as to cover the MTJ element 400. The bit line BL (and bit line contact) is formed on the insulator layer 82 so as to be coupled to the MTJ element 400.

Through the above-described steps, the MTJ element of the present embodiment is formed.

After that, a predetermined manufacturing step is performed, thereby ending the process of manufacturing the MTJ element of the present embodiment and the MRAM that includes the MTJ element of the present embodiment.

### (c) Conclusion

The magnetoresistive effect element (e.g., MTJ element) of the present embodiment includes the lower electrode having a concave cross-sectional shape. The upper face of the lower electrode has a shape (a convex shape) with a convex part facing a downward direction (the substrate side).

In the magnetoresistive effect element of the present embodiment, a plurality of magnetic layers and a tunnel barrier layer are disposed above the lower electrode.

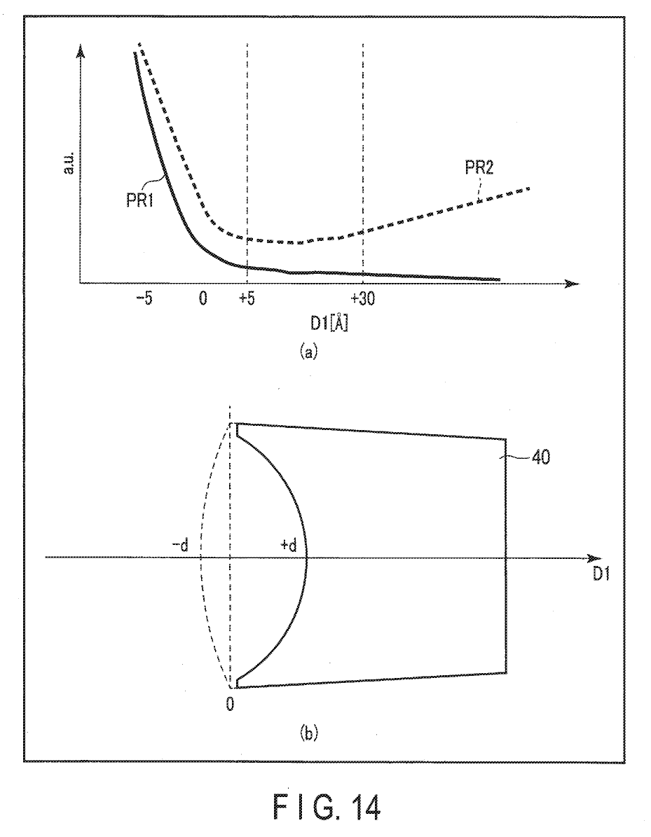

FIG. 14 is a diagram illustrating an example of the properties of the magnetoresistive effect element of the first embodiment.

In FIG. 14, (a) is a graph showing an example of a relationship between a shape of the lower electrode and a failure rate in the magnetoresistive effect element of the present embodiment.

In (a) of FIG. 14, the horizontal axis of the graph corresponds to a degree (unit: A) of the difference in level of the upper face (the face closer to the side where the magnetic layers are formed) of the lower electrode, and the vertical axis of the graph corresponds to a write error rate and a shunt failure rate (unit: arbitrary unit) of the MTJ element.

The write error rate (WER) is a rate of occurrence of an error that prevents magnetization switching at a time of writing data. The write error rate (WER) is indicated by a line PR2 in the graph.

The shunt failure rate (SFR) is a rate of occurrence of a failure due to a short-circuit of the storage layer and the reference layer of the MTJ element. The shunt failure rate (SFR) is indicated by a line PR1 in the graph.

In FIG. 14, (b) is a diagram illustrating a correspondence relationship between the values on the horizontal axis of the graph shown in (a) of FIG. 14 and the shape of the upper face of the lower electrode.

As shown in (b) of FIG. 14, a case where the upper face of the lower electrode is flat corresponds to 0 on the horizontal axis of the graph shown in (a) of FIG. 14. A case where the upper face of the lower electrode has a convex shape facing an upward direction (a case where the lower electrode has a convex cross-sectional shape) corresponds to a negative value on the horizontal axis of the graph shown in (a) of FIG. 14. A case where the upper face of the lower electrode has a convex shape facing a downward direction corresponds to a positive value on the horizontal axis of the graph shown in (a) of FIG. 14.

As shown in the graph of (a) of FIG. 14, the write error rate PR2 decreases as the shape of the upper face of the lower electrode changes from the convex shape facing an upward direction to the convex shape facing a downward direction.

For example, if the depth of the depression of the lower electrode of the MTJ element according to the present embodiment is within a range of 5 Å to 30 Å, the write error rate of the MTJ element of the present embodiment becomes the lowest.

If the lower electrode has a convex upper face facing a downward direction, the shunt failure rate PR1 of the MTJ element also decreases, as compared to a case where the lower electrode has a convex upper face facing an upward direction.

When the lower electrode has a convex upper face facing a downward direction, as described in the present embodiment, the stress of the magnetic field and the influence of the stray magnetic field that occur in the magnetic layers and the tunnel barrier layer are alleviated by the bending of the magnetic layers and the tunnel barrier layer attributed to the lower electrode.

Also, in the present embodiment, the stress acting to the magnetic layers and the tunnel barrier layer becomes relatively large due to the bending of the respective layers on the upper face of the lower electrode. Such effect of the stress applied to the magnetic layers and the tunnel barrier layer is expected to inhibit generation of crystal defects of the magnetic layers and the tunnel barrier layer.

As a result, the MTJ element of the present embodiment can reduce the write error rate and the short-circuit failure rate.

A magnetic anisotropy of a perpendicular magnetization film depends on the crystallinity in a direction perpendicular to the layer faces of the magnetic layers (and the tunnel barrier layer). Therefore, the properties of an MTJ element that uses a perpendicular magnetization film are further improved by the stress acting in the perpendicular direction to the layer face of the layer.

Furthermore, an MTJ element that uses an in-plane magnetization film is obtained with substantially the same effect as the MTJ element that uses a perpendicular magnetization film.

In the MTJ element 400 of the present embodiment, the underlying layer between the storage layer 11 and the lower electrode 40 need not be provided. Also, in the present embodiment, the shift canceling layer 19 need not be provided between the upper electrode 49 and the reference layer 13.

As described above, according to the magnetic device of the first embodiment, the properties of the magnetic device (magnetoresistive effect element) can be improved.

### (2) Second Embodiment

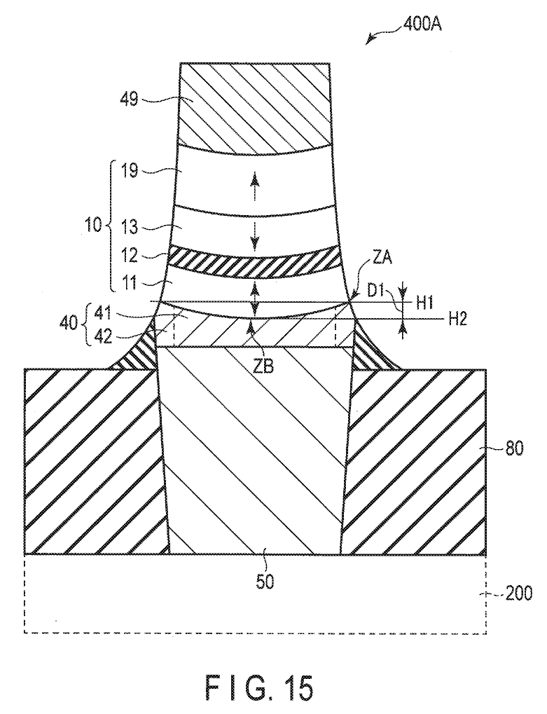

A magnetic device of a second embodiment will be described with reference to FIG. 15.

FIG. 15 is a schematic cross-sectional diagram illustrating the magnetic device (e.g., MTJ element) of the second embodiment.

An MTJ element 400A need not include an underlying layer between the magnetic layer 13 and the lower electrode 40, as shown in FIG. 15.

In the MTJ element 400A of the present embodiment, the magnetic layer (e.g., storage layer) 13 is provided on the lower electrode 40 having a concave shape.

The magnetic layer 13 directly contacts the upper face (depression) of the lower electrode 40.

The magnetic layer (shift canceling layer) 19 need not be provided between the upper electrode 49 and the magnetic layer 11.

In the present embodiment, the upper face of the lower electrode 40 has a convex shape facing a downward direction, in a manner similar to the first embodiment. In the lower electrode 40 having a concave cross-sectional shape, the position H1 of the upper end (edge) ZA of the upper face of the outer portion 42 is higher than the position H2 of the lower end (bottom) ZB of the upper face of the central portion 41.

In the MTJ element 400A of the present embodiment, each of the layers 11, 12, and 13 above the lower electrode 40 is bent to have a convex part facing a downward direction according to the shape of the lower electrode 40.

Thereby, the magnetic device (e.g., magnetoresistive effect element) of the present embodiment achieves substantially the same effects as the magnetic device of the first embodiment even if the underlying layer is not provided between the storage layer and the lower electrode. In the MTJ element 400A of the present embodiment, the shift canceling layer 19 need not be provided between the upper electrode 49 and the reference layer 13.

### (3) Third Embodiment

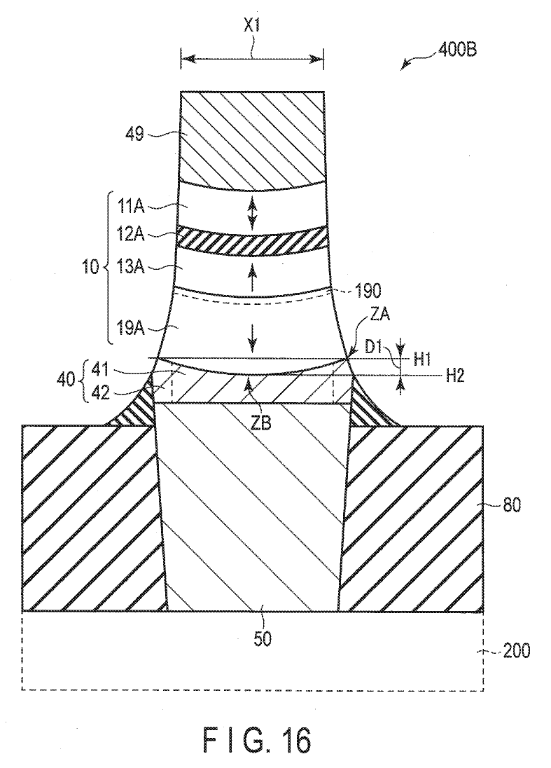

A magnetic device of a third embodiment will be described with reference to FIG. 16.

FIG. 16 is a schematic cross-sectional diagram illustrating the magnetic device (e.g., MTJ element) of the third embodiment.

In an MTJ element 400B, a storage layer 11A is provided on the upper electrode 49 side, and a reference layer 13A (and a shift canceling layer 19A) is (are) provided on the lower electrode 40 side, as illustrated in FIG. 16.

In the MTJ element 400B of the third embodiment, the reference layer 13A is located closer to the substrate 200 side than the storage layer 11A. The reference layer 13A is provided between the storage layer 11A and the substrate 200 (between a tunnel barrier layer 12A and the lower electrode 40). The storage layer 11A is provided between the tunnel barrier layer 12A and the upper electrode 49.

For example, a dimension of the reference layer 13A in the direction parallel to the surface of the substrate 200 is larger than a dimension of the storage layer 11A in the direction parallel to the surface of the substrate 200.

In the MTJ element 400B of the present embodiment, the underlying layer described using FIG. 5 may be provided between the shift canceling layer 19A and the lower electrode 40. Also, in the present embodiment, the shift canceling layer 19A need not be provided between the lower electrode 40 and the reference layer 13A.

In the present embodiment, the upper face of the lower electrode 40 has a convex shape facing a downward direction, in a manner similar to the first and second embodiments. Each of the layers 11A, 12A, 13A, and 19A above the lower electrode 40 is bent to have a convex part (a convex shape) facing a downward direction (the substrate side) according to the shape of the lower electrode 40.

Thereby, in the MTJ element of the present embodiment, the magnetic layers 11A, 13A, and 19A, and the tunnel barrier layer 12A have a convex cross-sectional shape facing the substrate side.

Therefore, the magnetic device of the present embodiment achieves substantially the same effects as the magnetic devices of the first and second embodiments.

### (4) Others

In above-described embodiments, a cell transistor of an example of a three-terminal switch element (select element) in FIGS. 1 to 3 is shown as an example of a switch element of a memory cell.

However, a circuit configuration using a two-terminal switch element described below can be applied to the above-described embodiments.

That is, the select transistor may be, for example, a switch element operating between two terminals. As one example, in a case where a voltage applied between the two terminals is equal to or less than a threshold, the switch element is in a “high resistance” state, for example, an electrically nonconductive state. In a case where a voltage applied between the two terminals is equal to or larger than a threshold, the switch element changes to a “low resistance” state, for example, an electrically conductive state. The switch element can be configured to perform this function regardless of a polarity of voltage.

In this example, the switch element may include at least one chalcogen element selected from among a group configured with tellurium (Te), selenium (Se), and sulfur (S). Alternatively, the switch element may include chalcogenide that is a compound including the chalcogen element. In addition to this, the switch element may contain at least one element selected from among the group configured with boron (B), aluminum (Al), gallium (Ga), indium (In), carbon (C), silicon (Si), germanium (Ge), tin (Sn), arsenic (As), phosphorus (P), and Sb (antimony).

The embodiments show an example of using an MRAM as the memory device employing the magnetic devices (magnetoresistive effect elements) of the present embodiments. However, the magnetic devices of the present embodiments may be applied to magnetic memories other than MRAM. The magnetic devices of the present embodiments may also be applied to devices other than a memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic device comprising:
a first electrode above a substrate, the first electrode including a first portion and a second portion adjacent to the first portion in a direction parallel to a surface of the substrate;
a second electrode above the first electrode;
a first magnetic layer between the first electrode and the second electrode;
a second magnetic layer between the first magnetic layer and the second electrode; and
a non-magnetic layer between the first magnetic layer and the second magnetic layer,
wherein an upper face of the first portion is located closer to the substrate than an upper face of the second portion.

2. The magnetic device according to claim 1, wherein a position of an end portion of the non-magnetic layer in a direction perpendicular to the surface of the substrate is higher than a position of a central portion of the non-magnetic layer in the direction perpendicular to the surface of the substrate.

3. The magnetic device according to claim 1, wherein a distance between a lower end of the upper face of the first portion and an upper end of the upper face of the second portion, in a direction perpendicular to the surface of the substrate, has a value within a range of from 0.5 nm to 3 nm.

4. The magnetic device according to claim 1, wherein when a dimension of the second electrode in the direction parallel to the surface of the substrate is denoted by “X”, and a difference in level between the upper face of the first portion and the upper face of the second portion in a direction perpendicular to the surface of the substrate is denoted by “D”, a value of D/X is within a range of from 0.01 to 0.1.

5. The magnetic device according to claim 1, wherein the upper face of the first electrode has a convex shape facing the substrate.

6. The magnetic device according to claim 1, wherein the first magnetic layer contacts an upper face of the first electrode.

7. The magnetic device according to claim 1, further comprising a contact plug provided between the substrate and the first electrode and coupled to the first electrode, wherein:
an upper face of the contact plug contacts a bottom face of the first electrode;
the upper face of the contact plug is flat; and
the bottom face of the first electrode is flat.

8. The magnetic device according to claim 1, further comprising a first layer provided between the first magnetic layer and the first electrode,
wherein an upper face of the first layer has a convex shape facing the substrate.

9. The magnetic device according to claim 1, wherein the first magnetic layer and the non-magnetic layer are bent.

10. A magnetic device comprising:
a first electrode above a substrate;
a second electrode above the first electrode;
a first magnetic layer between the first electrode and the second electrode;
a second magnetic layer between the first magnetic layer and the second electrode; and
a non-magnetic layer between the first magnetic layer and the second magnetic layer,
wherein an upper face of the first magnetic layer has a convex shape facing the substrate.

11. The magnetic device according to claim 10, wherein an upper face of the first electrode has a convex shape facing the substrate.

12. The magnetic device according to claim 10, wherein the first electrode has a concave cross-sectional shape.

13. The magnetic device according to claim 10, wherein the first electrode has a depression in a surface of the first electrode on a side of the first magnetic layer.

14. The magnetic device according to claim 13, wherein the depression has a depth within a range of from 0.5 nm to 3 nm in a direction perpendicular to a surface of the substrate.

15. A magnetic device comprising:
a first electrode above a substrate;
a second electrode above the first electrode;
a first magnetic layer between the first electrode and the second electrode;
a second magnetic layer between the first magnetic layer and the second electrode; and
a non-magnetic layer between the first magnetic layer and the second magnetic layer,
wherein the first magnetic layer is bent toward the substrate.

16. The magnetic device according to claim 15, wherein the non-magnetic layer is bent toward the substrate.

17. The magnetic device according to claim 15, wherein:
the first electrode has a first face on a side of the first magnetic layer; and
the first face is depressed toward the substrate.

18. The magnetic device according to claim 15, wherein the first face has a difference in level within a range of from 0.5 nm to 3 nm in a direction perpendicular to the surface of the substrate.

19. The magnetic device according to claim 15, wherein:
the first electrode has a second face opposed to the first face; and
the second face is flat.
